(19) United States
(12) Patent Application Publication
(10) Pub. No.: US 2012/0048083 A1
(43) Pub. Date: Mar. 1, 2012

(54) HIGH THROUGHPUT SAPPHIRE CORE PRODUCTION

(75) Inventors: Carl Richard Schwerdtfeger, Wilton, NH (US); Matthew Gary Klotz, Mont Vernon, NH (US); Chandra P. Khattak, Nashua, NH (US)

(73) Assignee: ADVANCED RENEWABLE ENERGY COMPANY LLC, Nashua, NH (US)

(21) Appl. No.: 13/224,130

(22) Filed: Sep. 1, 2011

Related U.S. Application Data
(60) Provisional application No. 61/379,358, filed on Sep. 1, 2010.

(51) Int. Cl. B26D 3/00; B24B 1/00; C30B 17/00; B23P 17/04; C30B 15/00; C30B 11/00

(52) U.S. Cl. 83/39; 117/13; 117/81; 117/82; 117/83; 29/592; 451/41

(57) ABSTRACT

A method for producing growth-axis oriented single crystal sapphire cores or near-net cores is provided. According to the method, a boule is grown on a desired growth axis having a first axial end and a second axial end. An orientation of a plane normal to the desired growth axis with respect to the boule is determined. The boule is then cored in a direction perpendicular to the plane to produce at least one growth-axis oriented single crystal sapphire core, or the boule is outer-diameter-grinded the boule to form a single crystal sapphire near-net core.

### CLAIM TO PRIORITY

The present application is a non-provisional of U.S. Provisional Appl. 61/379,358, of the same title, filed on Sep. 1, 2010.

### BACKGROUND

The present disclosure relates to fabrication of sapphire wafers, and more specifically to high throughput sapphire core production.

Sapphire is an anisotropic, rhombohedral crystal form of aluminum oxide that has multiple axes, designated a, m, r, and c. Each axis varies in thermal expansion, hardness, and optical properties. For example, the a-, m-, and r-, axes exhibit birefringence, while the c-axis does not. Furthermore, each of these orientations have different lattice spacings, and these spacings are also different from GaN layers that are typically grown on sapphire light emitting diode (LED) substrates.

Controlled single crystal growth processes typically involve the use of a seed crystal, wherein the seed crystal is oriented to achieve a desired growth direction. The crystal grown from the seed crystal is a larger single crystal having the same orientation as the seed and is referred to as a “boule.” Sapphire boules typically have a cylinder-like shape with a circumferential surface 105 and two axial ends 103 and 101 (i.e., top and bottom ends), as shown in FIG. 1. In some sapphire growth processes, growth of the boule generally occurs along the height of the boule from bottom to top along a crystal axis dictated by the orientation of the seed crystal, and is referred to as growth axis 108. For example, a seed oriented with the a-axis as the growth direction (referred to as an “a-axis seed”) will grow a boule such that the axis of the cylinder-like growth will be generally perpendicular to the a-plane and generally parallel to the a-axis. Such a boule is referred to as an “a-axis boule.” Similarly, m-axis boules are grown from m-axis seeds, r-axis boules are grown from r-axis seeds, and so on. Boules can be subsequently cored and/or ground, and then sliced into wafers. Consistent with boule terminology, an “a-axis core” also has circumferential surface that is perpendicular to the a-plane and parallel to the a-axis.

Currently, sapphire production processes generally grow crystals on a-, m- or r-orientations. However, for LED applications using sapphire as substrates for GaN layers, the closest match of lattice spacing to GaN is the c-axis orientation; thus, c-axis sapphire substrates are required. To satisfy these industry requirements, crystal growers obtain c-axis cores from a-axis or m-axis boules. For example, since the a-axis is perpendicular to the c-axis, c-axis cores can be obtained by coring in a direction parallel to the a-plane of the boule and perpendicular to the a-axis 208 (the growth axis) of the a-axis boule 200, as shown in FIGS. 2A and 2B. The same is true for m-axis boules.

This approach presents limitations, such as variation in core diameter and length, low material utilization, and multiple handling steps. Low material utilization results from the fact that a cross section of the boule is generally circular, and a circle does not have one consistent length; the maximum length is equal to the diameter of the boule, and the minimum length approaches zero. FIG. 2B shows a cross section of an a-axis boule. As illustrated in FIG. 2B, c-axis cores 207 obtained in a direction perpendicular to the growth axis of the a-axis boule 200 vary in length, and a great deal of the boule is unusable. In addition, the circumferential surface 205 of the boule must be cut, glued, and unglued to a surface using wax or epoxy to stabilize the boule during various grinding and coring steps. Therefore, each processing step requires additional time for cutting and gluing/waxing, introduces temperature variations as the glue/wax is applied and removed, and further increases the risk of damage to the crystal due to mishandling.

What is needed is a process which eliminates core length variation, maximizes material utilization, minimizes the number of handling steps, and reduces or eliminates the need for glues.

### SUMMARY

In one aspect, the present disclosure is directed to a method for producing growth-axis oriented single crystal sapphire cores or near-net cores. According to the method, a boule is grown on a desired growth axis having a first axial end and a second axial end. An orientation of a plane normal to the desired growth axis with respect to the boule is determined. The boule is then cored in a direction perpendicular to the plane to produce at least one growth-axis oriented single crystal sapphire core, or the boule is outer-diameter-ground to form a single crystal sapphire near-net core.

In another aspect, the present disclosure is directed to a method for producing c-axis oriented single crystal sapphire cores or near-net cores. According to the method, a c-axis boule having a first axial end and a second axial end is grown. A first axial surface at the first axial end is formed on the boule, and the boule is oriented to orient a c-plane of the boule such that the c-plane is parallel to a resurfacing plane of a resurfacing instrument. The first axial surface of the oriented boule is resurfaced to establish a resurfaced first axial surface that is parallel to the c-plane of the boule. A second axial surface at the second axial end is formed such that the second axial surface is parallel to the resurfaced first axial surface. The boule is cored in a direction perpendicular to the c-plane of the boule to form at least one c-axis oriented single crystal sapphire core, or outer-diameter ground to form a single crystal sapphire near-net core.

In another aspect, the boule is oriented so that the first axial surface is parallel to a desired plane, rather than parallel to a resurfacing plane of a resurfacing machine.

In yet another aspect, the present disclosure is directed to another method for producing c-axis oriented single crystal sapphire cores or near-net cores. According to the method, a c-axis boule having a first axial end and a second axial end is grown. A first axial surface is formed at the first axial end of the boule, and a second axial surface parallel to the first axial surface is formed at the second axial end of the boule. A c-plane of the boule is oriented such that the c-plane is parallel to a resurfacing plane of a resurfacing instrument. The first axial surface and the second axial surface are resurfaced so that each are parallel to the c-plane of the boule. The boule is then cored in a direction perpendicular to the c-plane of the boule to form at least one c-axis oriented single crystal sapphire core, or outer-diameter ground to form a single crystal sapphire near-net core. In another aspect, the boule is oriented so that the first axial surface is parallel to a desired plane, rather than parallel to a resurfacing plane of a resurfacing machine.

In another aspect, a method for processing a boule is disclosed. The method includes steps of placing a boule grown on a desired growth axis and having a first axial end and a second axial end into a gimbaled fixture having first and second rotary axes. The method also includes a step of determining an orientation of a plane normal to the desired growth axis with respect to the boule. The method also includes a step of forming a first axial surface at the first axial end of the boule, the first axial surface parallel to the plane.

In another aspect, a method for processing a boule is disclosed. The method includes a step of placing a boule grown on a c-axis, the boule having a first axial end and a second axial end, into a gimbaled fixture having first and second rotary axes, and determining an orientation of a plane normal to the c-axis with respect to the boule. The method also includes steps of orienting the boule using the first and second rotary axes of the gimbaled fixture so that the plane is parallel to a resurfacing plane of a resurfacing machine and forming a first axial surface at the first axial end of the boule, the first axial surface parallel to the resurfacing plane. In another aspect, the boule is oriented so that it is parallel to a desired plane, rather than parallel to a resurfacing plane of a resurfacing machine.

In another aspect, a fixture is disclosed, the fixture being suitable for orienting a workpiece, such as a boule, for machining or for grinding. The fixture includes independently-movable primary and secondary rotary axes, a primary (outer) ring and a secondary (inner) ring, the secondary ring having a support surface for supporting the workpiece. The secondary ring may optionally include at least one mount for ring contact retainers for the secondary ring. The secondary or inner ring is connected to at least one axle on the second rotary axis and the primary or outer ring is connected to at last one axle on the first rotary axis. Each axle is supported by at least one block. The fixture may be operated manually or may optionally include power drives where at least one axle of the first rotary axis is operably connected to a first power drive and at least one axle of the second rotary axis is operably connected to a second power drive, the power drives independently receiving input power and causing rotation of the at least one axle for the first rotary axis and the at least one axle for the second rotary axis. The fixture may be used with an x-ray diffraction system, including an x-ray emitter, an x-ray detector and a goniometer, and a control system, for detecting an orientation of the workpiece and for sending signals to a controller to manipulate the first and second power drives so that a desired plane of the workpiece is parallel to a resurfacing plane or so that a desired plane of the workpiece is oriented in a desired manner.

Another aspect of the present disclosure is a contoured fixture for mounting a boule for machining. The contoured fixture includes a contoured receiving portion, a plurality of adjustable blocks each having a contact portion. In one embodiment, the contacting portions may be flat and in another aspect they may be have contours that accommodate the corresponding contours of a boule. The contoured fixture may also include a plurality of bolts or other fasteners for mounting the fixture to a machine tool or grinder for processing.

Another aspect of the present disclosure is a device for machining a flat surface onto a workpiece, such as a boule. This method uses the fixtures disclosed herein and may be used to position the boule horizontally or vertically.

One aspect of the present disclosure is a fixture including a flat supporting surface, a retainer, and a plurality of fasteners mounting the retainer to the flat supporting surface, wherein the retainer contacts a circumferential surface of a workpiece mounted in the fixture. When the flat supporting surface and the retainer are separated a desired distance, the workpiece is held in place by a frictional force between the retainer and the workpiece. In one embodiment, the workpiece is mounted in an axial direction between the flat supporting surface and the retainer. In one embodiment, the mounted workpiece is suitable for machining an axial surface onto the workpiece. Another embodiment may also include spacer sleeves between the flat supporting surface and the retainer. In another embodiment, the device for machining further includes a horizontal support mounted perpendicularly to the flat supporting surface.

In yet another embodiment, the retainer discussed in the above paragraph includes a first and a second portion, each portion further including a groove and two lips, the groove suitable for mounting a preformed packing for contact between the retainer first and second portions and the workpiece. The retainer first and second portions may be reversibly joined by fasteners.

In another embodiment, a fixture is disclosed for machining a flat surface onto a circumferential or side surface of a workpiece, such as a core or near net core. In one embodiment, the machining fixture includes a horizontal base and a vertical base mounted perpendicularly to the horizontal base. The fixture also includes at least one contact portion within the horizontal base, at least one compression portion atop the horizontal base and at least one fastener removably securing the compression portion to the horizontal base. In another embodiment, the machining fixture also includes at least one spring between the compression portions and the horizontal base.

### BRIEF DESCRIPTION OF THE FIGURES

The disclosure and the following detailed description of certain embodiments thereof may be understood by reference to the following figures:

FIG. 1 depicts a typical single crystal sapphire boule;

FIGS. 2A-2B depict a conventional process of extracting c-axis cores from an a-axis boule;

FIGS. 3A and 3B depict extraction of c-axis cores from c-axis boules in accordance with the method of the present disclosure;

FIGS. 4A-4I depict the shape and orientation of a boule as it is processed at each of the various steps according to one embodiment of the present disclosure;

FIG. 5 depicts a boule fixture used in certain embodiments of the process of the present disclosure;

FIGS. 6a and 6b depict another boule fixture used in certain embodiments of the process of the present disclosure;

FIG. 7 depicts an orienting fixture used in certain embodiments of the process of the present disclosure;

FIGS. 8A-8B depict a core having an a-flat;

FIGS. 9A-9F depict the shape and orientation of a boule as it is processed at each of the various steps according to another embodiment of the present disclosure;

FIGS. 10A and 10B depict a fixture used in certain embodiments of the present disclosure for forming an a-flat surface on c-axis cores;

FIG. 11 depicts a boule having an offset between a growth axis and a physical central axis; and

FIG. 12 depicts an additional fixture using for processing boules.

### DETAILED DESCRIPTION

The following description includes various embodiments according to the present disclosure and accompanying figures. It should be appreciated that the figures are intended to provide a general understanding of the process and are not necessarily to scale.

The process according to the present disclosure provides efficient processing of boules that eliminates core length variation within a boule, maximizes material utilization, minimizes the number of handling steps, and reduces or eliminates the need for glues. These features are particularly advantageous for large boules, for example, boules having a diameter up to and greater than 260 mm and weighing up to and more than about 100 kg. Sapphire is a brittle material that is prone to damage from handling. This problem is exacerbated with large diameter boules, which are heavy and difficult to handle. The present disclosure includes various mechanical fixtures to fix the boule in place during processing. The fixtures described herein may be movable so that a boule may be moved from one physical location to another to be further processed in various processing tools without removing the boule from the fixture. For example, a boule may be fixed within a fixture and the fixture may be moved from an orienting device, such as an x-ray diffraction system, to a resurfacing device, such as a rotary grinder or a table grinder. The fixture may itself be fixed within a processing tool, for example, by using a vacuum, magnetic, or hydraulic chuck. On the other hand, the fixtures described herein may remain stationary as a boule is processed therein. For example, a fixture may remain in a processing station and various tooling equipment within the processing station may perform processing operations on the fixed boule.

The process according to the present disclosure is capable of producing “near-net” cores. Near-net cores are formed from minimal processing of boules, for example, by minimal grinding as opposed to coring. After circumferential surface grinding, near-net cores are ready for slicing into large diameter wafers, for example, 10, 12, and up to 26 inches. A near-net core may differ in radius from its original boule size by only a few millimeters. For example, a 6″ (150 mm) diameter c-axis near-net core can be grown from a 6.3″ (160 mm) diameter c-axis boule. The boule is outer-diameter (“OD”) ground down (i.e., the circumferential surface is ground down to establish a smaller radius) to obtain a 6″ near-net core. Thus, a near-net core is just slightly smaller in diameter than the originally grown boule.

Near-net cores can only be produced when the orientation of the original boule matches the orientation of the desired core. Thus, c-axis near-net cores can only be produced from c-axis boules. Conventional sapphire growth processes typically grow a-axis boules and core perpendicularly for c-axis cores. Therefore, such processes cannot achieve near-net c-axis cores. For near-net cores, the present disclosure may simply require OD grinding and no coring, which results in significant decrease in labor costs and a significant increase in yield. Also, near-net coring produces a single large core from a boule with minimal material waste, thereby giving high yields.

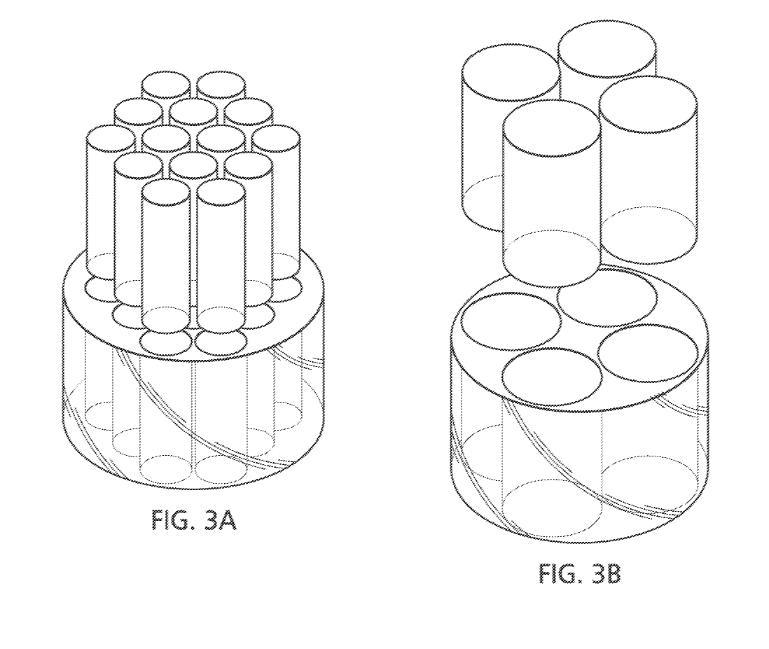

For boules much larger than the desired core diameter, the near-net approach may not be applicable, and multiple cores may be processed from each boule. The present disclosure provides an aspect of vertical coring where the cores thus produced all have the same length. For example, a c-axis boule having a 260 mm diameter and a length of 150 mm, can yield fourteen 2-inch cores 150 mm in length, as shown in FIG. 3A or four 4-inch cores 150 mm in length, as shown in FIG. 3B. Obtaining multiple c-axis cores from a c-axis boule will give lower yields compared to near-net coring, but the yield is still higher than obtaining c-axis cores from a-axis boules. In addition, the present approach may provide substantial advantages for subsequent processing. Cores and near-net cores formed from a boule of a given size in accordance with the present disclosure have a consistent diameter along their lengths, and are consistent in shape and size with respect to each other. Same-size cores obtained using the process of the present disclosure may be sized to fill a tray for a wire saw, as opposed to custom cutting cores to fill a tray or partially filling trays at different levels from run to run. Traditional sapphire processes (i.e., production of c-axis cores from a-axis boules) are unable to provide consistent core lengths, because round cores are extracted perpendicular to the growth axis of circular boules.

The embodiments described herein refer to c-axis boules. However, the process is applicable to producing r-axis, n-axis, and a-axis cores. For applications where c-axis wafers are used, c-axis boules processed in accordance with the present disclosure achieve significantly higher yields than, for example, a-axis boules processed into c-axis cores, because c-axis boules produce cores that can be processed into near-net cores with minimal material removal. In addition, cores of the same orientation as the growth axis of the boule, even if they are not near-net, can produce higher yields than conventional processes where the desired core orientation is different from the boule orientation (for example, processing c-axis cores from a-axis boules). Moreover, such cores are uniform in length, thereby simplifying processing and lowering costs. Typical yields for near net cores can be about 80%. Same orientation cores that are not near-net can be about 50%, compared to yields of only about 30% achieved by conventional a-axis boule processes where the desired core has a different orientation from the boule from which it is obtained.

For silicon on sapphire (SOS) applications, the desired sapphire substrate has an r-orientation, which is approximately 60 degrees from the c-axis. Therefore, for the reasons discussed above, it is desirable to extract r-axis cores from r-axis boules to achieve high yields, preferably by producing near-net cores. Procedures for extracting cores for SOS from r-axis boules are similar to extracting c-axis cores for LED from c-axis grown boules.

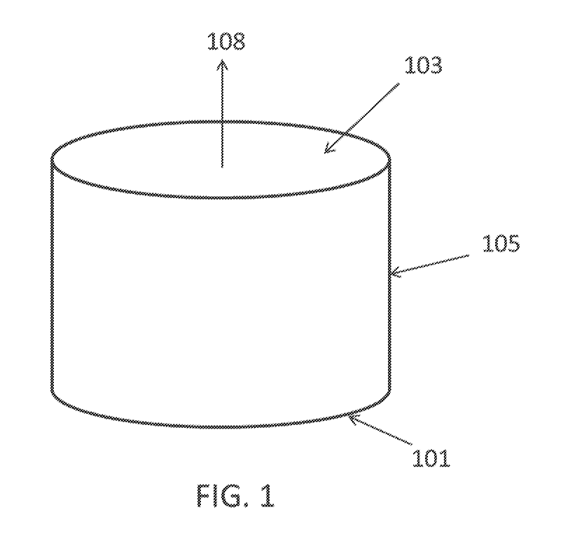

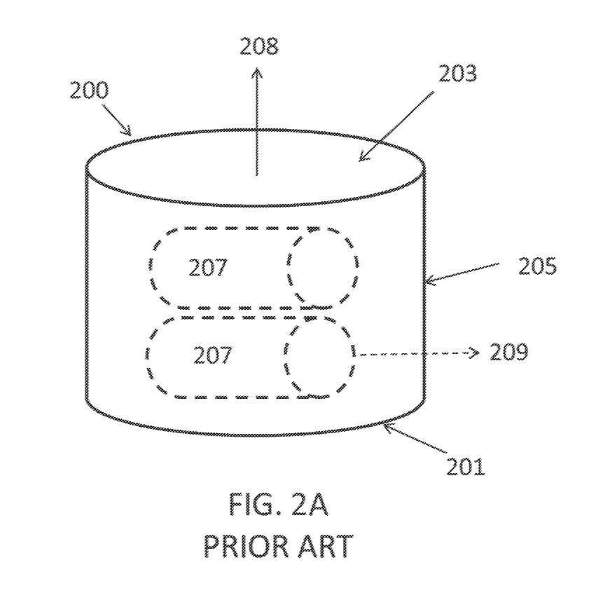

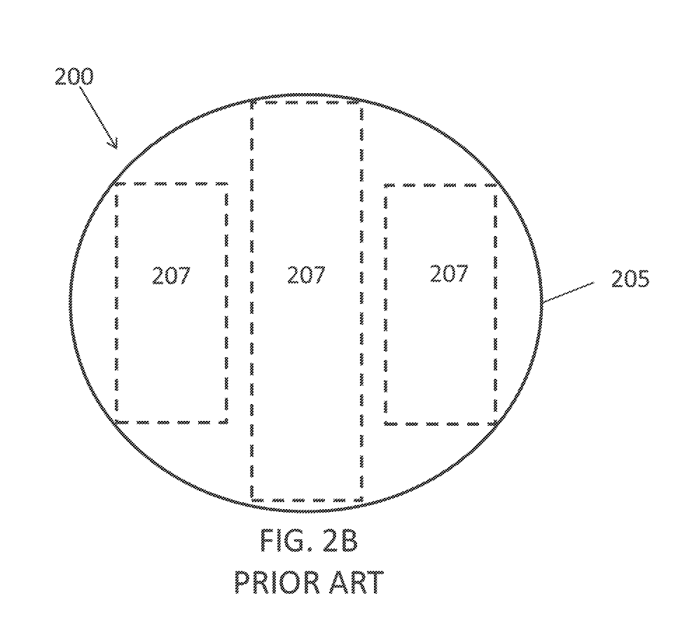

Sapphire boules that are processed in accordance with the present disclosure can be formed from various single crystal growth processes, including the Czochralski method (Cz); Kyropolous method (Ky); Vertical Bridgman (VB) method and variants of VB; Horizontal Bridgman (HB) method and variants of HB; Heat Exchanger Method (HEM); Gradient Freeze (GF) and variants of GF; and Controlled Heat Extraction System (CHES), the last being described in U.S. patent application Ser. Nos. 12/588,656, 12/909,471, and 13/095,073, the entireties of all of which are incorporated herein by reference. Such boules typically have a cylinder-like shape with a circumferential surface and two axial ends (i.e., top and bottom ends), as shown in FIG. 1. While the bulk of the boule has a generally cylindrical-like shape, its axial ends may require cutting and/or grinding in order to achieve flat axial end surfaces.

Some of the above mentioned processes utilize a crucible, and a boule formed therein generally takes on the inverted shape of the interior of the crucible. Various crystal growers have developed proprietary crucible designs having a particular shape to facilitate the growth and extraction processes. For example, a boule may have a cone-like taper at its bottom. In other processes, a seed crystal is dipped into and pulled/rotated from a melt. Growth occurs on the seed, and the size of the crystal may be controlled by the speed of removal/rotation from the melt. Depending on the crystal growth process, the diameter of the cylinder-like shape can vary greatly. For example, “pulled” crystals may vary in diameter depending on the pulling mechanism and accuracy of heat controls. Diameters of boules grown in crucibles can also vary as a result of factors including distortion of the crucible at high temperatures, thickness of the crucible, thermal expansion of the crucible material, and shape of the solid-liquid interface during growth, among other things. These factors are important in determining whether or not epoxies and glues are required or whether mechanical fixturing is adequate for processing of boules to cores. Boules produced in accordance with the disclosures of U.S. patent application Ser. Nos. 12/588,656, 12/909,471, and 13/095,073 are generally consistent in size and shape and therefore are well suited for mechanical fixturing.

In the method according to the present disclosure, a boule is processed in a sequence of steps to produce growth-axis oriented single crystal sapphire cores or a near-net core. For example, the method can include growing a boule on a desired growth axis having a first axial end and a second axial end. For LED applications, the desired growth axis may be c-axis, while for SOS applications, the desired growth axis may be r-axis. Alternatively, the desired growth axis may be a-axis or m-axis.

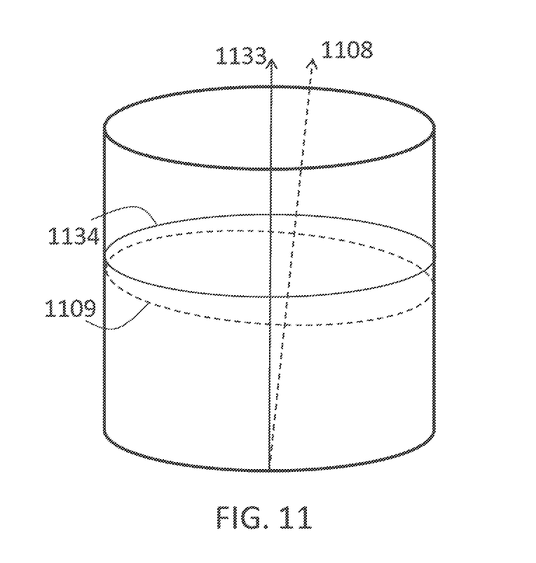

It should be appreciated that the growth axis of a boule typically is not precisely co-axial with the physical central axis of the boule. This is offset is illustrated in FIG. 11, which is an exaggerated depiction of the deviation of the growth axis from the physical central axis of the boule. The physical central axis 1133 of the boule is normal to a cross sectional plane of the boule, 1134, while the growth axis 1108 deviates from the physical central axis at an angle. As a result, the plane corresponding to the growth axis 1109 is not usually co-planar with a horizontal cross sectional plane 1134 normal to the physical central axis 1133 of the boule. Therefore, it is necessary to determine the orientation of a plane normal to the desired growth axis with respect to the boule. This is done typically using x-ray diffraction analysis. Once the orientation of the plane is determined, the boule can be cored in a direction perpendicular to the plane to produce at least one growth-axis oriented single crystal sapphire core. In the alternative, the boule can be OD ground to form a single crystal sapphire near-net core. In some embodiments, a first axial surface is formed at the first axial end of the boule and a second axial surface is formed at the second axial end of the boule prior to coring. The first and second axial surfaces are parallel to the plane normal to the desired growth axis. In other embodiments, first and second axial surfaces are formed on the cores or single near-net core, rather than the boule.

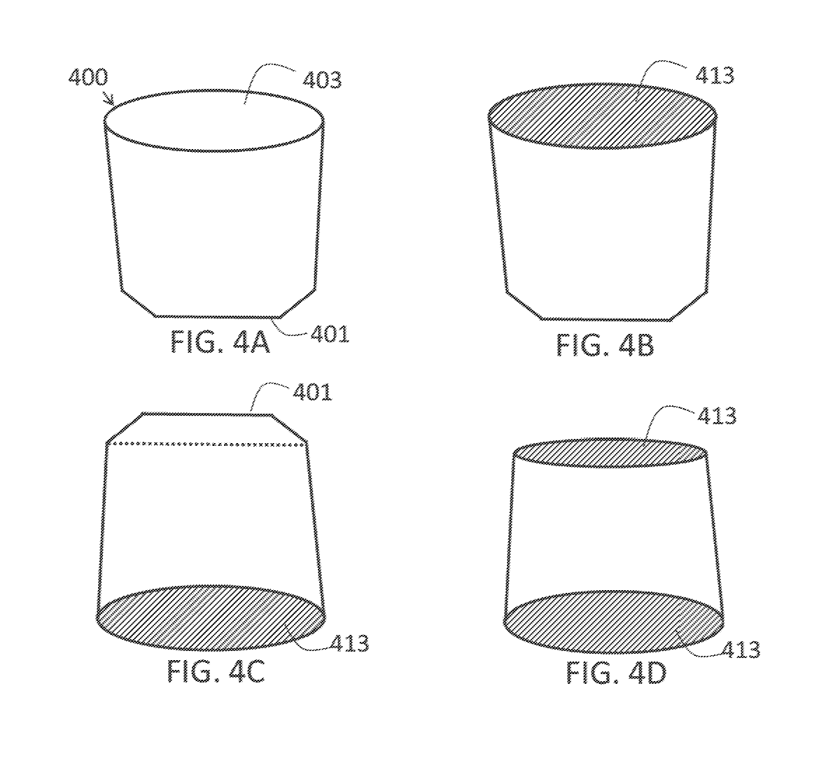

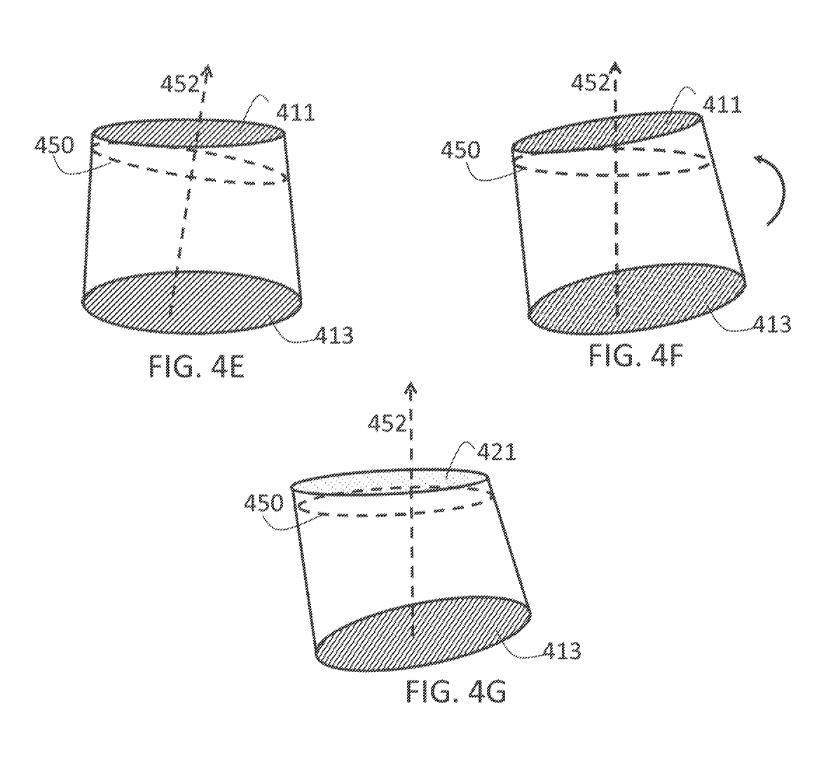

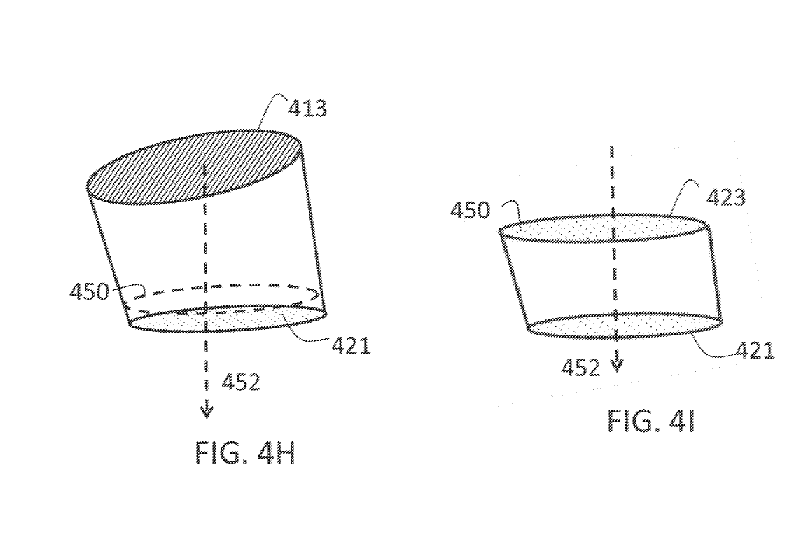

The shape and orientation of the boule at each of the various steps of one embodiment is shown in FIGS. 4A-4I. For clarity, these figures do not show fixturing devices used during processing. In an embodiment according to the present disclosure as shown in FIGS. 4A-4I, a c-axis boule 400 is extracted from a crucible and placed in a fixture such that the first axial end 403 (top) of the boule faces up (FIG. 4A). In cases where the second axial end 401 (bottom) of the boule is contoured and cannot be fixed to a flat supporting surface, a contoured mechanical fixture that accepts the shape of the bottom of the boule is used. Mechanical fixturing overcomes the need for waxes and glues, which are generally limited to use with flat supporting surfaces and require additional time for the wax or glue to set.

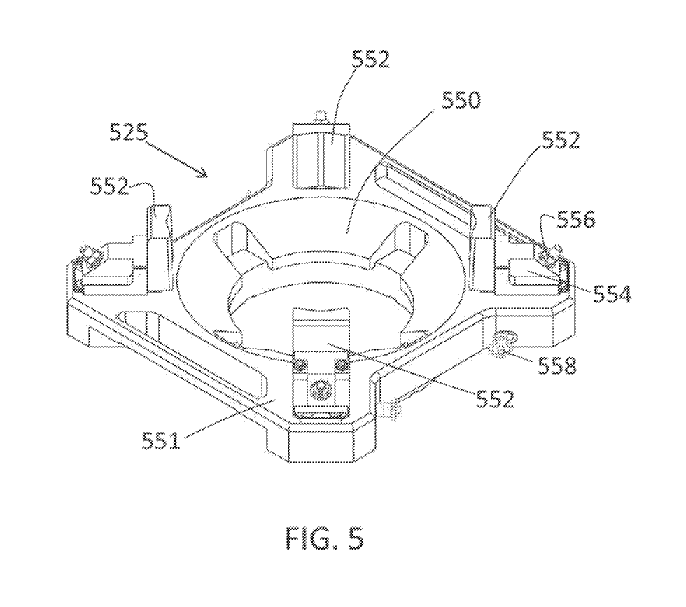

The process according to some embodiments of the present disclosure may use a contoured mechanical fixture such as the one shown in FIG. 5. The contoured fixture 525 has a base portion 551 and a contoured receiving portion 550 that accepts a contoured boule. The fixture 525 also includes a plurality of movable blocks 554 that are mountable to the base portion 551 with fasteners 556, such as bolts. The moveable blocks each have a contact portion 552, which contact a circumferential surface of the boule. For tapered boules, these portions can be angled to follow the tapered contour of the boule, and can be inverted to accommodate an inverted tapered boule. The contact portions may also feature flat surfaces for contacting the boule. The moveable portions are removable from the base portion 551 and also adjustable such that the distance of the contact portions 552 from the contoured portion 550 can be varied to accommodate any variations in boule shape. In addition, a plate having a top flat surface (not shown) can be fitted in the contoured receiving portion 550, so that a boule having a flat axial end can be supported thereby. The contoured fixture 525 may also include additional fasteners 558, such as bolts, for mounting the contoured fixture to a machine tool, such as a grinder, for processing, such as grinding an axial surface or sawing an axial surface.

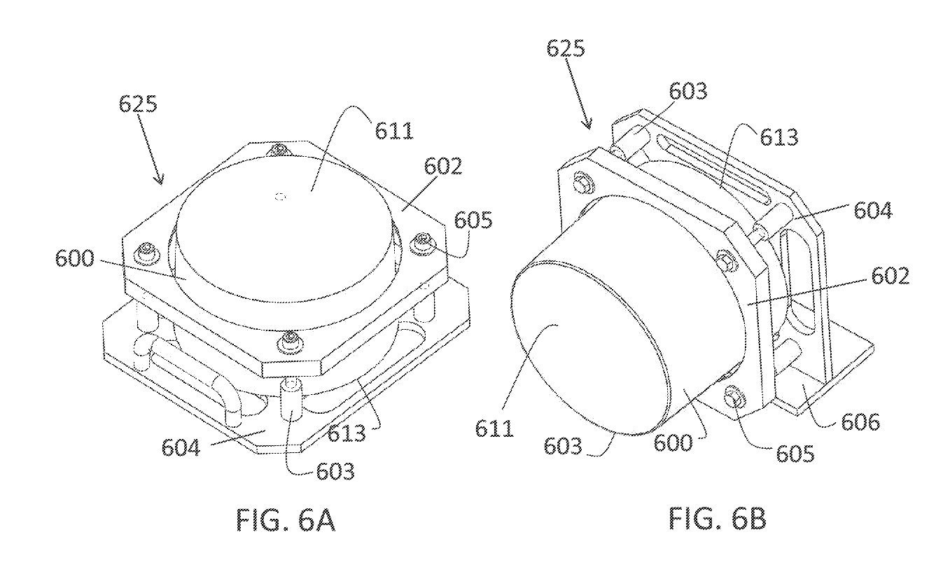

The fixtured boule is then placed under a grinding tool and the first axial end 403 of the boule is ground down to form a flat first axial surface 413, as shown in FIG. 4B. In FIG. 4C, the boule is then removed from the fixture and inverted onto this first axial surface 413 in a second mechanical fixture, such as the one shown in FIGS. 6A and 6B, which have a flat supporting surface 604 to accommodate the flat first axial surface (FIG. 4C). As shown in FIGS. 6A and 6B, the fixture can be configured to hold the boule both vertically and horizontally, so that the second axial end of the boule can be cut and/or ground in a either a horizontal position or a vertical position. This reduces the number of handling steps, as the boule may remain in the same fixture during both cutting and grinding. Referring to FIG. 4D, a flat second axial surface 411 is formed at the second axial end of the boule. The second axial surface 411 is generally parallel to the first axial surface 413.

The boule 600 shown in the fixture of FIGS. 6A and 6B is slightly tapered such that the diameter increases along the height of the boule from the second axial surface 611 to the first axial surface 613. The fixture 625 takes advantage of this shape by using a retainer 602 that contacts the circumference at a particular height of the boule. The retainer 602 of the fixture has a fixed inner diameter that slides down the length of the boule 600 until the retainer 602 reaches a diameter of the boule that is substantially equal to the inner diameter of the retaining portion. The retainer is fastened to the supporting surface, thus clamping down on the boule. The frictional force between the inner diameter of the retaining portion and the circumference of the boule compresses the boule against the flat supporting surface 604 of the fixture, allowing the fixture to hold the boule in place. The retainer may be compressed down, for example, by threaded sleeves 603 and fasteners 605. This configuration is desirable for machining an axial surface, such as a c-plane surface, onto the boule or workpiece. A horizontal support 606 can be added so that the fixture holds the boule horizontally, as shown in FIG. 6B. In this configuration, the fixture and the boule may be mounted for sawing, e.g., by a vertically-moving blade in a saw.

Referring again to FIG. 4D, after the second axial surface 411 is established (FIG. 4D), the boule 400 is ready to be oriented. As illustrated in FIG. 4E, the c-plane 450 corresponding to the growth axis 452 of a c-axis boule typically is not precisely co-planar to the axial surfaces 411 and 413 of the boule. Therefore, the first axial surface 411 and second axial surface 413 must be resurfaced in order to align them with the c-plane 450, within about ±0.1 degrees. To achieve this, the boule is moved to an orienting fixture and positioned so that the c-plane 450 of the boule is parallel to a resurfacing plane of a resurfacing instrument. Such orienting of the boule is shown in FIG. 4F. As used herein, the term “resurfacing plane” refers to the plane of a surface formed by a resurfacing instrument. Referring to FIG. 4F, the resurfacing plane is assumed to be a horizontal plane, so the c-plane 450 of the boule is oriented horizontally. An orienting fixture is capable of orienting the boule to align the c-plane of the boule with the resurfacing plane. The orienting fixture includes a surface that is rotatable about two orthogonal axes.

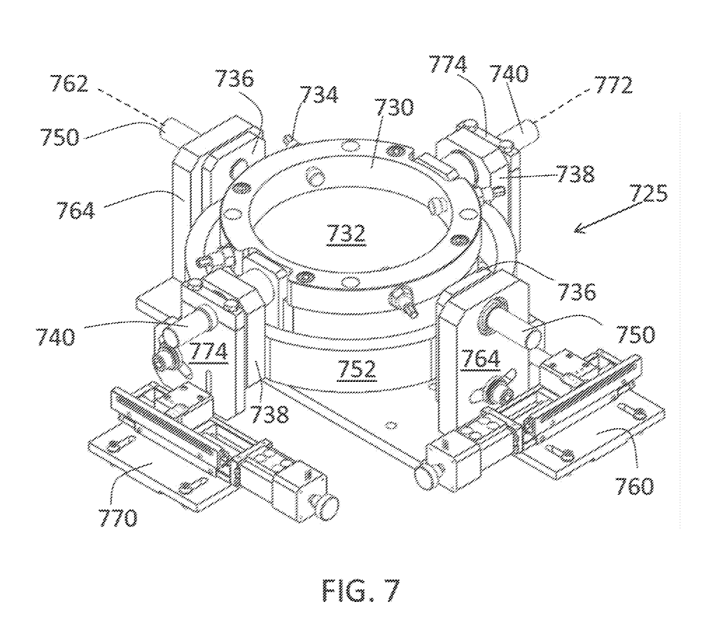

For example, the orienting fixture 725 of FIG. 7 is a gimbal, which has two orthogonal axes of rotation, 762 and 772, thereby allowing the boule to be easily moved with respect to the two axes such that the c-plane of the boule can be positioned in a desired orientation. In this fixture, the secondary axis of rotation 772 is associated with the inner or secondary ring 730, and the primary axis of rotation 762 is associated with the outer or primary ring 752. It is understood that the primary and secondary axes of rotation are orthogonal. The inner ring 730 includes a bottom support surface 732 for an axial surface of the boule and optionally includes a plurality of ring contact retainers 734 for positive location controls on the boule within the ring. The ring contact retainers may affix to the inner ring through mounts (such as threaded orifices) of the inner ring. The secondary ring is mechanically supported on axles 740 and blocks 738. One block may interface with a secondary axis pivot plate 774, which may be pivoted by actuator 770 to adjust the position or tilt of the secondary ring. The primary ring 752 is supported on axles 750 and blocks 764. The blocks may each include at least one bearing and other mechanical devices such as grease fittings, lubricated packings or other lubricating devices suitable for allowing rotary movement of the axles. One of the blocks 764 may interface with a pivot plate 736 which may be pivoted by actuator 760 to adjust the position or tilt of the primary ring.

The orienting fixture may optionally include automation components (not shown) for automatically adjusting the rotary positions of the primary and secondary rings corresponding to each axis, so that orientation of the boule can be performed without human operation. The orienting fixture 725 may be used in conjunction with an x-ray diffraction system (which includes an x-ray emitter, detector, and a goniometer) to position the boule such that the c-plane (corresponding to the growth axis of the boule) is parallel to a desired plan, for example a, resurfacing plane. In one embodiment, the planes are parallel if they are within about ±0.1 degrees of each other. The diffraction properties of the crystal are analyzed to establish the orientation of the axes of the boule, and the boule is reoriented to position the plane as needed. For example, if the resurfacing plane is a horizontal plane (i.e., if the resurfacing plane corresponds to a horizontal grinding surface), the boule is oriented so that a c-plane of the boule is horizontal. In cases where the boule has a taper along its length (i.e., circumference of the boule decreases along its length), the orienting fixture may include an additional fitting (not shown), such as a tapered ring, that surrounds the boule, allowing the boule to be placed in the fixture both top side up and bottom side up.

After the c-plane of the boule is oriented, as shown in FIG. 4F, the first and second axial surfaces 413 and 411 are resurfaced to form resurfaced first and second axial surfaces 423 and 421, respectively such that each are parallel to the c-plane of the boule. For example, the oriented boule is contacted by the resurfacing plane while oriented in the orienting fixture, and the first and second axial surfaces are ground down so that they are co-planar to the c-plane corresponding to the growth axis of the boule. In one embodiment of the present disclosure, the boule remains in the orienting fixture and the second axial surface is resurfaced to form a resurfaced second axial surface 421 (FIG. 4G). The boule is then inverted (FIG. 4H) and the first axial surface is resurfaced to form a resurfaced first axial surface 423 (FIG. 4I).

A boule processed in accordance with the above described steps has first and second axial surfaces that are coplanar with the c-plane of the boule, and the boule can be cored to produce one or more cores, or outer-diameter (“OD”) ground to produce a single near-net core. In one embodiment, the first and second axial surfaces are parallel if they are oriented within about ±0.1 degrees of each other.

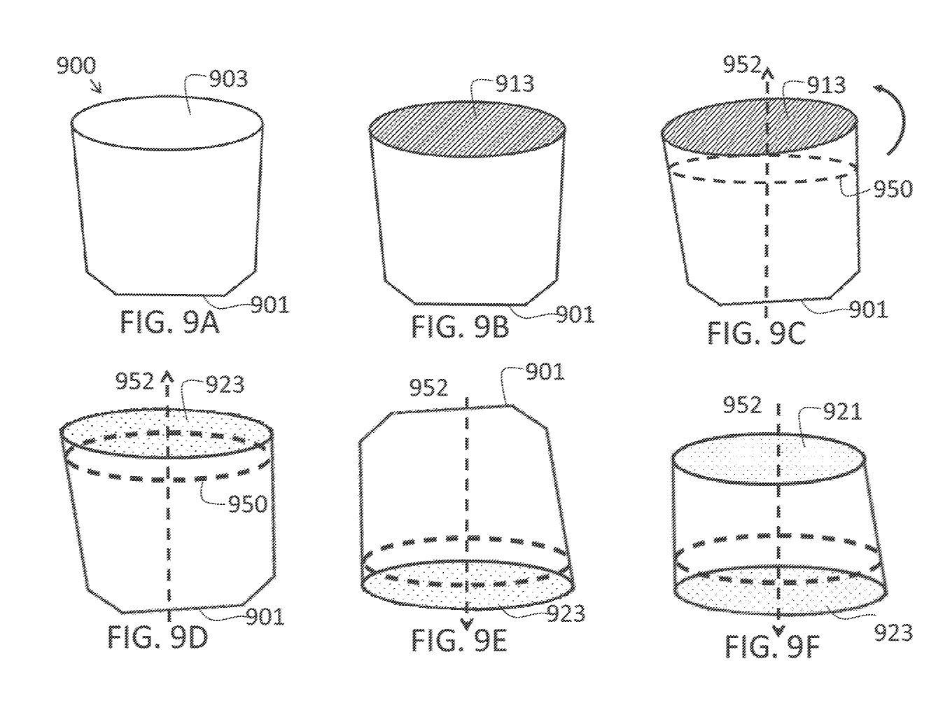

The sequence of another embodiment according to the present disclosure is shown in FIGS. 9A-9F. Referring to FIG. 9A, a boule 900 is extracted from a crucible and placed directly into an orienting fixture (such as the one shown in FIG. 7) such that the first axial end 903 (top) of the boule faces up. In cases where the second axial end 901 (bottom) of the boule is contoured and cannot be fixed to a flat supporting surface, the orienting fixture may include a contoured surface that accepts the shape of the bottom of the boule.

Referring again to FIG. 9A, the boule is fixed with its first axial end 903 (i.e., top of the boule) facing up. Referring to FIG. 9B, the boule is ground down to form a flat first axial surface 913 at the first axial end, for example, by positioning the boule under a horizontal grinding tool. Referring to FIG. 9C, after grinding, the boule remains in the orienting fixture and is oriented such the c-plane 950 of the boule is parallel to a resurfacing plane. Once oriented in the fixture, the top of the boule is ground to resurface the first axial surface of the boule to establish a resurfaced first axial surface 923 that is parallel to the c-plane 950 of the boule and perpendicular to the growth axis 952, as shown in FIG. 9D. The boule remains in the orienting fixture during all of the above mentioned steps. Referring to FIG. 9E, after forming the resurfaced first axial surface 923, the boule is removed from the orienting fixture and inverted such that the second axial end 901 faces up (i.e., bottom side up) into a second fixture, such as the one shown in FIGS. 6A and 6B. A second axial surface 921 is then formed at the second axial end, for example, by cutting and/or grinding. As shown in FIG. 9F, the second axial surface 921 thus formed is parallel to the resurfaced first axial surface. A boule processed in accordance with the above steps has first and second axial surfaces that are coplanar with c-plane of the boule, and the boule can be cored to produce one or more cores, or OD ground to produce a single near-net core.

This embodiment of the present disclosure, which uses only two fixtures, eliminates or minimizes the need for glues or waxes and minimizes the number of times a boule must be handled. Limiting the frequency of handling reduces the risk of damage to the boule during processing, thereby reducing yield loss. In addition, the reduced number of handling steps represents a significant reduction in processing time.

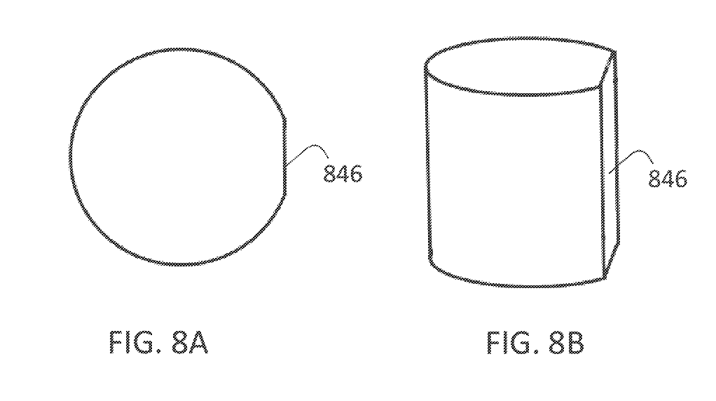

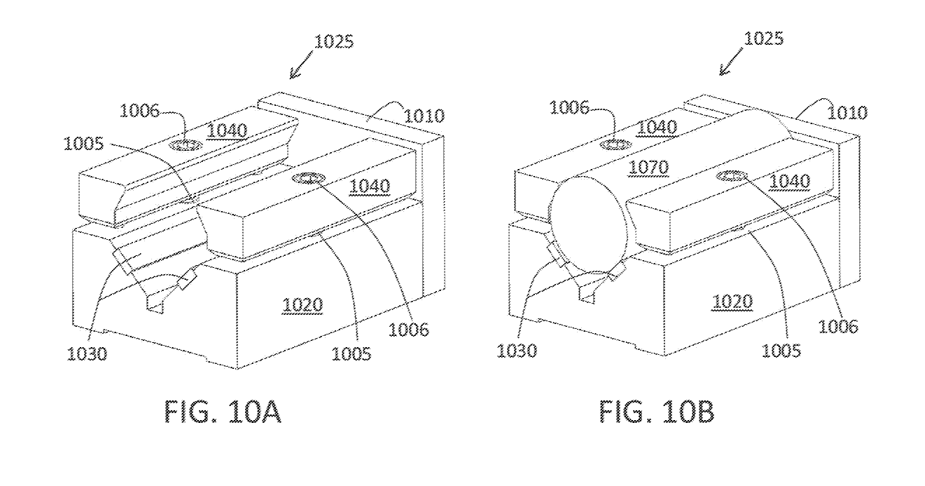

Optionally, the cores or near-net core thus produced can be further oriented to determine an a-plane, and subsequently provided an “a-flat” surface prior to slicing the cores or near-net core into wafers. Referring to FIGS. 8A and 8B, the a-flat 846 is a flat surface is formed on the circumferential surface of the c-axis core and is co-planar to the a-plane of the crystal. A fixture such as the one shown in FIGS. 10A and 10B may be used to form the a-flat surface. The a-flat fixture 1025 includes a vertical base 1010 and a horizontal base 1020, so that a core fixed within the a-flat fixture can be positioned both horizontally and vertically. The vertical base 1010 and the horizontal base 1020 may be securely fastened to each other by fasteners, so that the core is fixed in a horizontal position.

As shown in FIGS. 10A and 10B, the fixture is positioned horizontally. The core 1070 is placed so that its circumferential surface is supported by contact portions 1030, which are formed from a plastic low-friction material, such as polytetrafluoroethylene, so that the core is not damaged from compressive forces. The core may be rotated while inside the fixture, for example, to allow for orientation of the core by x-ray diffraction. The a-plane can be determined and the core oriented, for example, such that the a-plane is horizontal when the core is positioned horizontally. Once the core is oriented, compression portions 1040, which may be spring loaded by springs 1005, are fixed, for example, by securing bolts 1006. Compression portions 1040 thus fix the vertical position of the workpiece or core. Compression portions 1040 may be made from a soft light metal, such as aluminum, or a plastic material, or any material which will not damage the core while firmly retaining the core or workpiece in place. When positioned in the fixture 1025, in one embodiment, a significant portion of the circumferential surface of the core is enclosed. The exposed portion of the circumferential surface protrudes above the height of the compression portion 1040, and can be cut or ground down to form the a-flat surface. After the core is fixed, the a-flat fixture may be moved to a grinding or cutting station. The fixture is also capable of top and bottom grinding of the core if needed; the fixture can be positioned vertically and the core positioned within the fixture so that an axial end of the core protrudes from the end of the fixture. The protruded axial end can then be ground or cut.

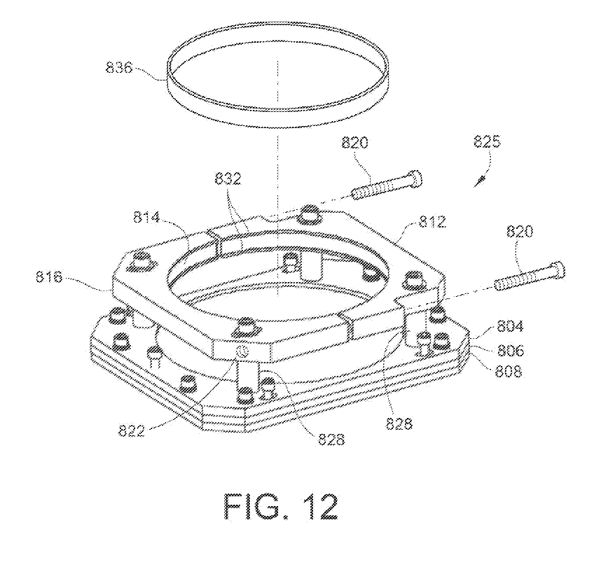

Another embodiment of a fixture is depicted in FIG. 12. This fixture is similar in function to those depicted in FIGS. 6A and 6B, in which a boule is placed for machining. The fixture 825 of FIG. 12 includes additional lateral support for the boule placed into the fixture. Fixture 825 includes a bottom or retaining plate 804 and may have one or more shim plates 806, 808 for convenience during operations. This bottom portion of the fixture may be held together with fasteners, such as bolts, as shown. The upper retaining portion of the fixture includes right and left retainer halves 812, 816 which may be joined with bolts 820 through orifices in the right retainer half 812 and threaded holes 822 in the left retainer half 816. The inner diameter of the left and right retainer halves include top and bottom lips 832 and a central or inner groove 814. The groove has a cross-sectional shape in a general form of a rectangle or rounded rectangle, for retention of a pre-formed packing 836. The preformed packing may have a shape of a thin ring. The fixture may be used with a series of preformed packings having a single outer diameter to match the upper retaining ring 812, 816, and a choice of inner diameters. The inner diameter may be chosen to match a given boule from the production line. The pre-formed packing is made of a somewhat resilient material, such as a harder elastomer, in order to firmly grip the boule without damaging the boule. The preformed packing can accommodate a tapered boule, regardless of whether it is top-side up or inverted.

In embodiments the process flow described herein may be provided in a fully or partially automated processing line, with physical, mechanical, and/or robotic handoff among processing stations, automated process monitoring, such as under computer control, and other computer- and robotics-based automation capabilities as may be understood by those of ordinary skill in the art.

While the invention has been described in connection with certain preferred embodiments, other embodiments would be understood by one of ordinary skill in the art and are encompassed herein.

All documents referenced herein are hereby incorporated by reference.

What is claimed is:

1. A method for producing growth-axis oriented single crystal sapphire cores or near-net cores comprising:
growing a boule on a desired growth axis having a first axial end and a second axial end;
determining an orientation of a plane normal to the desired growth axis with respect to the boule; and
coring the boule in a direction perpendicular to the plane to produce at least one growth-axis oriented single crystal sapphire core or outer-diameter-grinding the boule to form a single crystal sapphire near-net core.

2. The method of claim 1, further comprising the step of forming a first axial surface at the first axial end and a second axial surface at the second axial end that are parallel to the plane, prior to coring the boule.

3. The method of claim 1, further comprising a step of forming an a-flat surface in the single crystal sapphire core or single crystal sapphire near-net core.

4. The method of claim 1, wherein the step of coring the boule produces multiple cores having the same shape and size.

5. The method of claim 1, wherein the boule is fixed in at least one fixture prior to coring or outer-diameter grinding.

6. The method of claim 5, wherein the fixture is an orienting fixture.

7. The method of claim 6, wherein the orienting fixture is a gimbal.

8. The method of claim 5, wherein the at least one fixture is movable from one physical location to another while the boule is fixed therein.

9. A method for producing c-axis oriented single crystal sapphire cores or near-net cores comprising:
growing a c-axis boule having a first axial end and a second axial end;
forming a first axial surface at the first axial end;
orienting the boule to orient a c-plane of the boule such that the c-plane is parallel to a resurfacing plane of a resurfacing instrument;
resurfacing the first axial surface of the oriented boule to establish a resurfaced first axial surface that is parallel to the c-plane of the boule;
forming a second axial surface at the second axial end such that the second axial surface is parallel to the resurfaced first axial surface; and
coring the boule in a direction perpendicular to the c-plane of the boule to form at least one c-axis oriented single crystal sapphire core or outer-diameter-grinding the boule to form a single crystal sapphire near-net core.

10. A method for producing c-axis oriented single crystal sapphire cores or near-net cores comprising:
growing a c-axis boule having a first axial end and a second axial end;
forming a first axial surface at the first axial end of the boule;
forming a second axial surface parallel to the first axial surface at the second axial end of the boule;
orienting a c-plane of the boule such that the c-plane is parallel to a resurfacing plane of a resurfacing instrument;
resurfacing the first axial surface and the second axial surface so that each are parallel to the c-plane of the boule; and
coring the boule in a direction perpendicular to the c-plane of the boule to form at least one c-axis oriented single crystal sapphire core or outer-diameter-grinding the boule to form a single crystal sapphire near-net core.

11. A method for processing a boule comprising:
placing a boule grown on a desired axis and having a first axial end and a second axial end into a gimbaled fixture having first and second rotary axes;
determining an orientation of a plane normal to the desired axis with respect to the boule; and
forming a first axial surface at the first axial end of the boule, the first axial surface parallel to the plane.

12. The method of claim 11, further comprising forming a second axial surface at the second axial end of the boule, the second axial surface parallel to the plane.

13. The method of claim 11, further comprising growing the boule on the desired axis.

14. The method of claim 11, wherein the orientation is accomplished by analyzing diffraction properties of the boule.

15. The method of claim 11, further comprising coring the boule produce to at least one core.

16. A method for processing a c-axis boule comprising:
placing a boule grown on a c-axis and having a first axial end and a second axial end into a gimbaled fixture having first and second rotary axes;
determining an orientation of a plane normal to the c-axis with respect to the boule;
orienting the boule using the first and second rotary axes of the gimbaled fixture so that the plane is parallel to a resurfacing plane of a resurfacing machine; and
forming a first axial surface at the first axial end of the boule, the first axial surface parallel to the resurfacing plane.

17. The method of claim 16, further comprising forming a second axial surface at the second axial end of the boule, the second axial surface parallel to the plane normal to the c-axis.

18. The method of claim 16, wherein the resurfacing plane is a resurfacing plane of a rotary grinder or a table grinder.

19. The method of claim 16, further comprising coring the boule in a direction perpendicular to the plane to produce at least one growth-axis oriented single crystal sapphire core or outer-diameter-grinding the boule to form a single crystal sapphire near-net core.

20. The method of claim 19, further comprising slicing the core or near-net core into wafers.
